(19) United States
(12) Patent Application Publication
(10) Pub. No.: US 2026/0173323 A1
(43) Pub. Date: Jun. 18, 2026

(54) HEAT SINK ASSEMBLY FOR METER SOCKET ADAPTER

(71) Applicant: ConnectDER, Inc., Philadephia, PA (US)

(72) Inventors: Brian Matthew Aiken, Boulder, CO (US); Maria Lauren Tabbut, Media, PA (US)

(73) Assignee: ConnectDER, Inc., Philadephia, PA (US)

(21) Appl. No.: 18/978,538

(22) Filed: Dec. 12, 2024

(51) Int. Cl. H05K 7/20

(52) U.S. Cl. CPC H05K 7/20418; H05K 7/20445

(57) ABSTRACT

A heat sink assembly includes a metal portion that is electrically conductive and thermally conductive, the metal portion configured to couple to conductors of a meter socket adapter (MSA) to draw heat from the conductors of the MSA and a plastic portion that is electrically insulative and thermally conductive, the plastic portion coupled to the metal portion to transfer heat from the metal portion to an exterior of the MSA, wherein the plastic portion is molded over a part of the metal portion.

### TECHNICAL FIELD

The embodiments described and recited herein pertain, generally, to behind-the-meter electrical power management.

### BACKGROUND

Meter socket adapters (MSAs) conduct electricity to and from a meter socket, generating resistive heat in the process. A wattage of an MSA can be limited by the passive transfer of heat out of the MSA. Some active heat dissipation solutions include a fan to induce airflow to reduce a temperature of the MSA. However, fan failure can cause the MSA to overheat.

### SUMMARY

Various aspects of the disclosure may now be described with regard to certain examples and embodiments, which are intended to illustrate but not limit the disclosure. Although the examples and embodiments described herein may focus on, for the purpose of illustration, specific systems and processes, one of skill in the art may appreciate the examples are illustrative only, and are not intended to be limiting.

Aspects of the present disclosure are directed to a heat sink assembly, including a metal portion that is electrically conductive and thermally conductive, the metal portion configured to couple to conductors of a meter socket adapter (MSA) to draw heat from the conductors of the MSA, and a plastic portion that is electrically insulative and thermally conductive, the plastic portion coupled to the metal portion to transfer heat from the metal portion to an exterior of the MSA, where the plastic portion is molded over a part of the metal portion.

In some implementations, the metal portion includes a first metal portion and a second metal portion, the first metal portion coupled to a first conductor of the conductors of the MSA and the second metal portion coupled to a second conductor of the conductors of the MSA. In some implementations, the plastic portion includes blades to increase a surface area of the plastic portion. In some implementations, the metal portion includes a lateral part that extends laterally within the plastic portion. In some implementations, the lateral part extends laterally over at least 50% of an area of the plastic portion. In some implementations, an exterior surface of the plastic portion is flush with a housing of the MSA. In some implementations, the plastic portion has anisotropic thermal conductivity, and where the plastic portion has a higher thermal conductivity in a first direction towards an exterior surface of the plastic portion than in a second direction parallel to the exterior surface of the plastic portion. In some implementations, the plastic portion is not grounded. In some implementations, the plastic portion is an injection-molded thermoplastic including additives that increase the thermal conductivity of the thermoplastic.

Aspects of the present disclosure are directed to a meter socket adapter (MSA), including a first conductor configured to electrically couple to a meter socket, a second conductor configured to electrically couple to an electrical meter, a housing, and a heat sink assembly, including a metal portion that is electrically conductive and thermally conductive, the metal portion configured to couple to the first conductor and the second conductor to draw heat from the first conductor and the second conductor, and a plastic portion that is electrically insulative and thermally conductive, the plastic portion coupled to the metal portion to transfer heat from the metal portion to an exterior of the housing, where the plastic portion is molded over a part of the metal portion.

In some implementations, the metal portion includes a first metal portion and a second metal portion, the first metal portion coupled to the first conductor and the second metal portion coupled to the second conductor. In some implementations, the plastic portion includes blades to increase a surface area of the plastic portion. In some implementations, the metal portion includes a lateral part that extends laterally within the plastic portion. In some implementations, the lateral part extends laterally over at least 50% of an area of the plastic portion. In some implementations, an exterior surface of the plastic portion is flush with the housing. In some implementations, the plastic portion has anisotropic thermal conductivity, and where the plastic portion has a higher thermal conductivity in a first direction towards an exterior surface of the plastic portion than in a second direction parallel to the exterior surface of the plastic portion. In some implementations, the plastic portion is not grounded. In some implementations, the plastic portion is an injection-molded thermoplastic including additives that increase the thermal conductivity of the thermoplastic.

Aspects of the present disclosure are directed to a method for manufacturing a heat sink assembly for a meter socket adapter (MSA), the method including positioning a metal portion of the heat sink assembly within a mold, the metal portion configured to couple to conductors of the MSA, and forming a plastic portion of the heat sink assembly by injecting a thermoplastic including additives to increase thermal conductivity into the mold such that the plastic portion is molded over a part of the metal portion.

In some implementations, the mold is configured such that the plastic portion includes blades that are curved to be flush with a cylindrical housing of the MSA.

The foregoing summary is illustrative only and is not intended to be in any way limiting. In addition to the illustrative aspects, embodiments, and features described above, further aspects, embodiments, and features may become apparent by reference to the following drawings and the detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different FIGS. indicates similar or identical items.

FIG. 1 is a perspective view of an example meter socket adapter (MSA) including heat sink assemblies.

FIG. 2 is a side view of the MSA of FIG. 1.

FIG. 3 illustrates example conductors of an MSA.

FIG. 4 illustrates the conductors of FIG. 3 coupled to heat sink assemblies.

FIG. 5 is a perspective view of an example heat sink assembly.

FIG. 6 is a side view of the heat sink assembly of FIG. 5.

FIG. 7 is a cross-section view of the heat sink assembly of FIG. 6.

FIG. 8 is a front view of the heat sink assembly of FIG. 5.

FIG. 9 is a cross-section view of the heat sink assembly of FIG. 8.

FIG. 10 is a perspective view of the second segment of the metal portion 514 of the heat sink assembly of FIG. 5.

FIG. 11A is a front view of the second segment of FIG. 10.

FIG. 11B is a side view of the second segment of FIG. 10.

FIG. 11C is a bottom view of the second segment of FIG. 10.

FIG. 12 is a perspective view of the first segment of the metal portion of the heat sink assembly of FIG. 5.

FIG. 13A is a front view of the first segment of FIG. 12.

FIG. 13B is a side view of the first segment of FIG. 12.

FIG. 13C is a bottom view of the first segment of FIG. 12.

FIG. 14 is a flow chart illustrating operations of a method for manufacturing a heat sink assembly for an MSA.

The foregoing and other features of the present disclosure may become apparent from the following description and appended claims, taken in conjunction with the accompanying drawings. Understanding that these drawings depict only several embodiments in accordance with the disclosure and are therefore, not to be considered limiting of its scope, the disclosure may be described with additional specificity and detail through use of the accompanying drawings.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It may be readily understood that the aspects of the present disclosure, as generally described herein, and illustrated in the figures, may be arranged, substituted, combined, and designed in a wide variety of different configurations, all of which are explicitly contemplated and made part of this disclosure.

Aspects of the present disclosure relate to heat sink assemblies and meter socket adapters (MSAs) including heat sink assemblies. Implementations and examples described herein include a heat sink assembly including a metal portion that is electrically and thermally conductive and a plastic portion that is electrically insulative (i.e., isolative) and thermally conductive, where the plastic portion is molded over a part of the metal portion such that the metal portion is partly embedded in the plastic portion. In this way, there is good thermal contact between the metal portion and the plastic portion, facilitating transfer of heat from the metal portion to the plastic portion. The metal portion is configured to be coupled to internal components of an MSA to draw heat from the internal components to be transferred out of the MSA into ambient air by the plastic portion. As the plastic portion is electrically isolative, the internal components can carry electricity without causing an electrical shock risk at an external surface of the heat sink assembly. The electrical isolating property of the plastic portion means that the heat sink assembly does not need to be grounded, significantly reducing a complexity of manufacture and installation of the MSA. Furthermore, molding the plastic portion over a part of the metal portion simplifies manufacture and maintenance of the heat sink assembly. Thus, the heat sink assembly can efficiently and safely transfer heat from the interior components of the MSA to the ambient air without any moving parts and with high reliability.

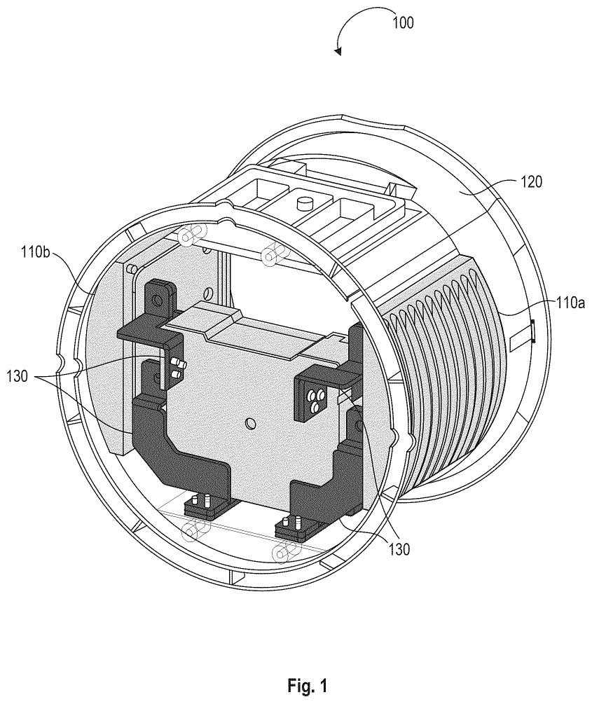

FIG. 1 is a perspective view of an example meter socket adapter (MSA) 100 including heat sink assemblies 110. The MSA 100 includes a housing 120 and heat dissipation conductors 130. The housing 120 is configured to align with and be sized according to a meter socket such that the MSA 100 can be interposed between the meter socket and a utility meter. Electrical conductors (not shown in FIG. 1) of the MSA 100 can conduct electricity between the meter socket and the utility meter. In some implementations, the conductors 130 are coupled (electrically coupled and/or thermally coupled) to the electrical conductors of the MSA 100 to draw heat from the electrical conductors. The conductors 130 are coupled to the heat sink assemblies 110 such that the heat sink assemblies 110 can transfer heat from the conductors 130 to an exterior of the MSA 100, or outside the housing 120. In this way, the heat sink assemblies 110 can transfer heat from within the housing 120 to an external environment, or ambient air of the external environment. Dissipating heat from the MSA 100 into the ambient air allows the MSA 100 to conduct greater amounts of electricity and perform more functions than if the heat sink assemblies 110 were not included in the MSA 100.

The heat sink assemblies 110 can include a first heat sink assembly 110a and a second heat sink assembly 110b. In some implementations, the MSA 100 includes only one of the first heat sink assembly 110a and the second heat sink assembly 110b. In some implementations, the MSA 100 includes both of the first heat sink assembly 110a and the second heat sink assembly 110b. The heat sink assemblies 110 can extend through the housing 120 to transfer heat from the interior of the housing 120 to the exterior of the housing 120. As illustrated, the housing 120 can be cylindrical, with exterior surfaces of the heat sink assemblies 110 being flush with the surface of the housing 120. The heat sink assemblies 110 can include blades (also referred to herein as fins) to increase a surface area of the heat sink assemblies 110 to promote heat dissipation. As illustrated, an upper surface of the blades can be flush with the surface of the housing 120. The upper surface of the blades can be curved to be flush with a cylindrical surface of the housing 120.

In some implementations, the heat sink assemblies 110 have anisotropic thermal conductivity, where the heat sink assemblies 110 have a higher thermal conductivity in an outward direction (e.g., to dissipate heat out of the MSA 100) than in another direction, such as parallel to the exterior surface of the housing 120, or along the blades of the heat sink assemblies 110. In this way, the heat sink assemblies 110 can efficiently move heat out of the MSA 100.

The exterior surfaces of the heat sink assemblies 110 can include a plastic material that is electrically insulative (i.e., isolative). Thus, the exterior surface of the housing 120 and the heat sink assemblies 110 can be handled by personnel without shock risk. Additionally, the plastic material can have a lower heat capacity than metal, reducing the temperature of the exterior surfaces of the heat sink assemblies 110 and accordingly preventing burns due to high temperatures.

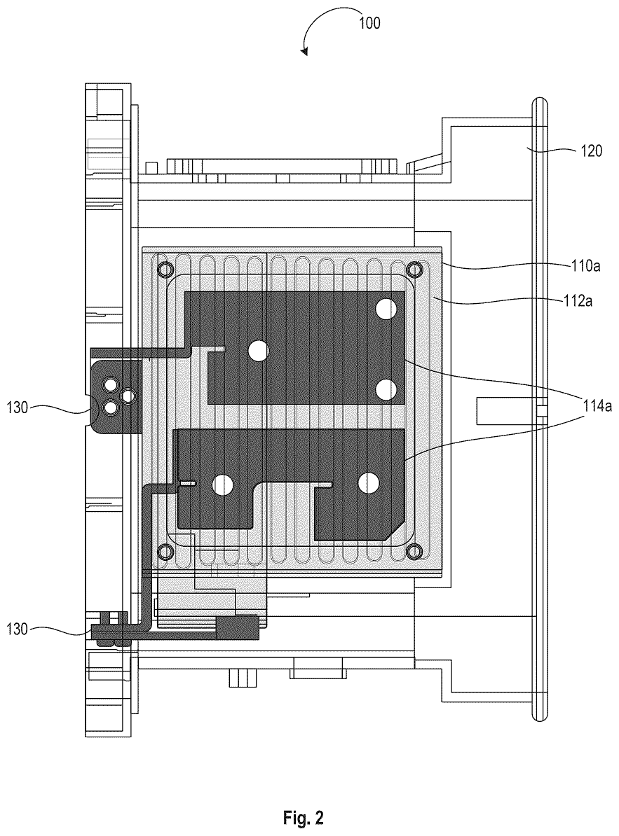

FIG. 2 is a side view of the MSA 100 of FIG. 1. In FIG. 2, the housing 120 of the MSA 100 is illustrated as semi-transparent in order to show the interconnection of various components. The first heat sink assembly 110a includes a plastic portion 112a and a metal portion 114a. The plastic portion 112a is illustrated as semi-transparent in order to show the metal portion 114a. While the housing 120 and the plastic portion 112a are illustrated as semi-transparent for purposes of illustration in FIG. 2, the housing 120 and the plastic portion 112a are, in most embodiments, opaque.

The metal portion 114a is partly embedded within the plastic portion 112a. The metal portion 114a is embedded within the plastic portion 112a to facilitate heat transfer from the metal portion 114a to the plastic portion 112a. The metal portion 114a includes lateral portions that extend laterally within the plastic portion 112a to facilitate heat transfer from the metal portion 114a to the plastic portion 112a. The lateral portions of the metal portion 114a may extend laterally (e.g., in two dimension) along the plastic portion 112a to increase an area of contact between the metal portion 114a and the plastic portion 112a. In an example, a part of the metal portion 114a is embedded within the plastic portion 112a and extends at least 75% of a horizontal length of the plastic portion 112a along a central axis of the MSA 100 and extends at least 75% of a vertical length of the plastic portion 112a along a circumference of the housing 120. In this example, the embedded part extends over at least 56% of the lateral area (e.g., area corresponding to the exterior surface) of the plastic portion 112a. The embedded part of the metal portion 114a can extend over any percentage of the lateral area of the plastic portion 112a. The larger the area of the part of the metal portion 114a embedded within the plastic portion 112a, the greater surface area between the embedded part and the plastic portion 112a. As the embedded part of the metal portion 114a is embedded within the plastic portion 112a, the embedded part has thermal connectivity for transferring heat from the metal portion 114a to the plastic portion 112a.

The metal portion 114a is coupled to the conductors 130 of the MSA 100. The conductors 130, as discussed herein, are coupled (e.g., mechanically, thermally, electrically) to electrical conductors of the MSA 100 that electrically connect the meter socket and the utility meter. In some implementations, the conductors 130 are part of, or included in, the electrical conductors of the MSA 100. The conductors 130 transfer heat from the electrical conductors of the MSA 100 to the metal portion 114a. Thus, the conductors 130, the metal portion 114a, and the plastic portion 112 form a thermal pathway from the electrical conductors, to the conductors 130, to the metal portion 114a, to the plastic portion 112a, to the ambient air outside the MSA 100. The conductors 130 can also transfer heat from other components of the MSA 100 to the metal portion 114a. Thus, resistive heat generated within the MSA 100 is transferred out of the MSA 100 via the first heat sink assembly 110a.

The plastic portion 112a forms an exterior surface of the first heat sink assembly 110a. The plastic portion 112a can include the blades of the first heat sink assembly 110a and can have anisotropic thermal conductivity, where the plastic portion 112a has a higher thermal conductivity in an outward direction (e.g., to dissipate heat out of the MSA 100) than in another direction, such as parallel to the exterior surface of the housing 120, or along the blades of the plastic portion 112a.

The second heat sink assembly 110b may include a plastic portion and a metal portion, similar to the plastic portion 112a and the metal portion 114a. In some implementations, the first heat sink assembly 110a and the second heat sink assembly 110b are identical. In some implementations, the first heat sink assembly 110a and the second heat sink assembly 110b are symmetrical. In some implementations, the first heat sink assembly 110a and the second heat sink assembly 110b have different dimensions and/or properties to account for asymmetric heat buildup within the MSA 100. The first heat sink assembly 110a and the second heat sink assembly 110b can have different numbers of fins, different plastic materials, different metal materials, and/or different dimensions of embedded metal parts. In an example, the first heat sink assembly 110a includes an embedded part of the metal portion 114a that is larger than a corresponding embedded part of the metal portion of the second heat sink assembly 110b to allow for greater heat transfer by the first heat sink assembly 110a than the second heat sink assembly 110b.

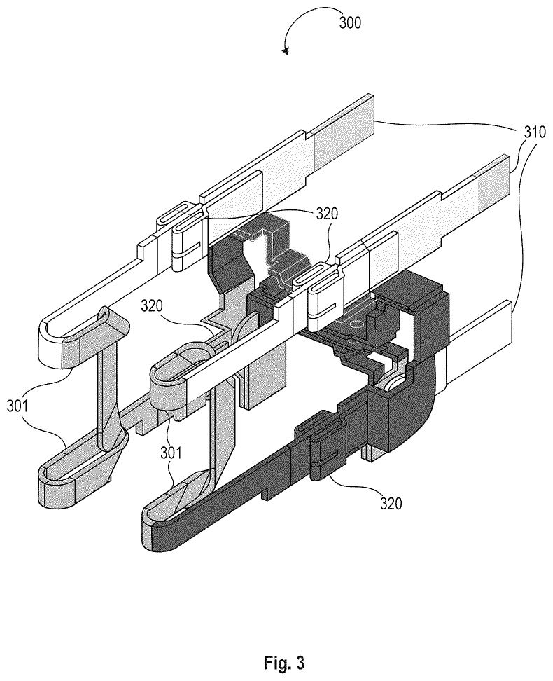

FIG. 3 illustrates example conductors 300. The conductors 300 include first conductors 310, second conductors 320, and utility meter conductors 301. The first conductors 310 and the second conductors 320 are part of an MSA, such as the MSA 100 of FIG. 1, while the utility meter conductors 301 are part of a utility meter. The first conductors 310 are configured to couple to a meter socket, with blades of the first conductors 310 configured to electrically couple with receptacles of the meter socket. The first conductors 310 can include four blades, corresponding to four receptacles of the meter socket. In some implementations, the first conductors 310 include five blades, corresponding to five receptacles of the meter socket, including a neutral receptacle. The second conductors 320 are configured to couple to a utility meter, with receptacles of the second conductors 320 configured to electrically couple with blades of the utility meter. Utility meter conductors 301 can include blades that are received by the receptacles of the second conductors 320. The second conductors 320 can include four receptacles configured to receive four blades of the utility meter. The first conductors 310 are coupled to the second conductors 320 to allow for electricity to pass from the meter socket to the utility meter conductors 301 and back to the meter socket.

The conductors 300 are color-coded in segments to illustrate temperature of the segments due to resistive heat generated within the conductors 300, with darker colors indicating higher temperatures. The temperature rises (i.e., increases in temperature over ambient temperature of the environment) of the segments of the conductors 300, as illustrated, range from about 60° C. to about 100° C. The conductors 300 may be included in an MSA that does not include heat sink assemblies such as the heat sink assemblies 110 of FIG. 1. The conductors 300 may transfer heat through the air within the housing of the MSA to the housing of the MSA which then transfers heat to the ambient air. This inefficient thermal pathway may cause the conductors 300 (and other internal components of the MSA) to reach temperatures above operating temperatures (e.g., above a 65° temperature rise over ambient air at 25° C.) of the internal components of the MSA and/or temperatures that cause an exterior surface of the MSA to pose a burn risk to personnel.

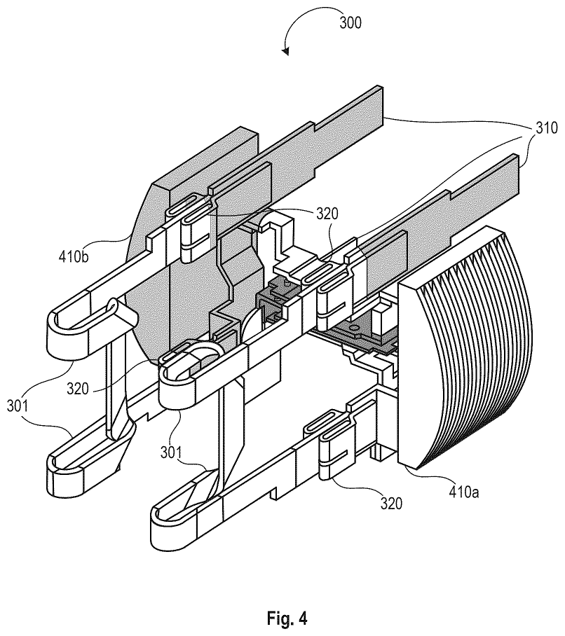

FIG. 4 illustrates the conductors 300 of FIG. 3 coupled to heat sink assemblies 410. The heat sink assemblies 410 include a first heat sink assembly 410a and a second heat sink assembly 410b. The heat sink assemblies 410 may be similar to, or the same as, the heat sink assemblies 110 of FIG. 1. The heat sink assemblies 410 can be coupled to the first conductors 310 and/or the second conductors 320. In an example, the first heat sink assembly 410a is coupled to two conductors of the first conductors 310 and two conductors of the second conductors 320 and the second heat sink assembly 410b is coupled to two conductors of the first conductors 310 and two conductors of the second conductors 320.

The conductors 300 are color-coded in segments to illustrate temperature of the segments due to resistive heat generated within the conductors 300, with darker colors indicating higher temperatures. With the heat sink assemblies 410 coupled to the conductors 300, the temperatures of the segments of the conductors 300, as illustrated, range from about 65° C. to about 90° C. under the same conditions as in FIG. 3. Thus, the heat sink assemblies 410 can keep the conductors 300 at lower temperatures than when operating without the heat sink assemblies 410. In an example, the heat sink assemblies 410 keep the temperature of the conductors 300 below a 65° temperature rise over ambient air at 25° C.

As discussed herein, the heat sink assemblies 410 are electrically insulative, such that current traveling through the conductors 300 is not carried through the heat sink assemblies 410, allowing the heat sink assemblies 410 to not be grounded. Grounding an MSA may be a difficult and time-consuming process. The heat sink assemblies 410, which do not need to be grounded, significantly simplify the installation of the MSA in the meter socket by not requiring a connection to ground.

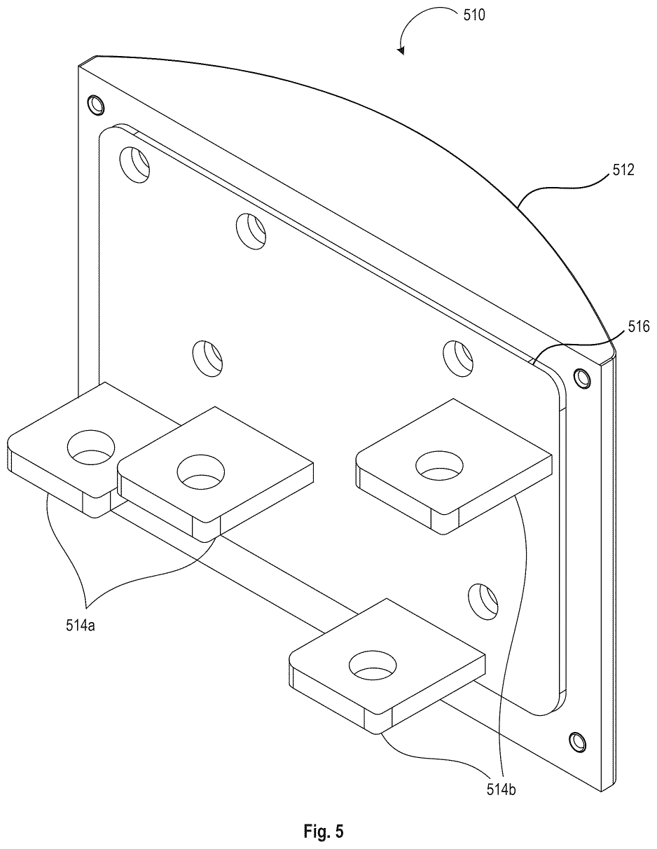

FIG. 5 is a perspective view of an example heat sink assembly 510. The example heat sink assembly 510 may be the same as, or similar to, the first heat sink assembly 110a or the second heat sink assembly 110b of FIG. 1. The heat sink assembly 510 includes a plastic portion 512 and a metal portion 514 including a first segment 514a and a second segment 514b. The heat sink assembly 510 can include a back plate 516 attached to a back (e.g., away from fins of the plastic portion 512) of the plastic portion 512. The metal portion 514 can include an embedded part and a protruding part, where the embedded part is embedded in the plastic portion 512 and the protruding part extends out of the plastic portion 512 and through the back plate 516. In FIG. 5, only the protruding part of the metal portion 514 that extends through the back plate 516 is shown.

The back plate 516 may include an electrically and/or thermally insulative material. The back plate 516 may insulate the embedded part of the metal portion 514 from internal components of an MSA to prevent unintended electrical connections and to prevent heat from traveling from the metal portion 524 into the MSA. The protruding part of the metal portion 514 may be coupled (i.e., thermally and electrically) to internal components of the MSA, such as the conductors 130 of FIG. 1 to transfer heat to the metal portion 514. The protruding portion of the first segment 514a and the protruding portion of the second segment 514b can be connected to different conductors and/or internal components of the MSA. The first segment 514a and the second segment 514b can be electrically isolated from each other, allowing different portions of electrical circuits within the MSA to transfer heat to the first segment 514a and the second segment 514b.

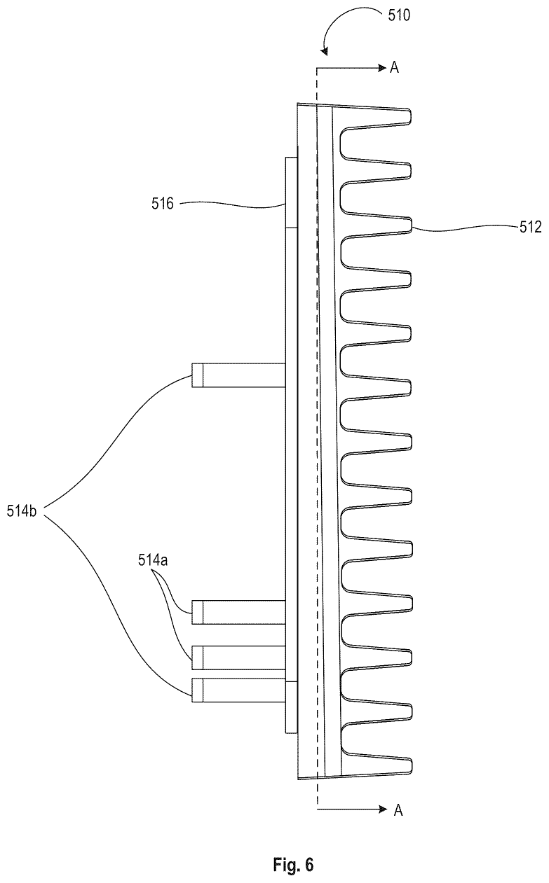

FIG. 6 is a side view of the heat sink assembly 510 of FIG. 5. As shown in FIG. 6, the heat sink assembly 510 can include blades in the plastic portion 512 to increase a surface area of the plastic portion 512 and increase a transfer of heat from the plastic portion 512 to the ambient air.

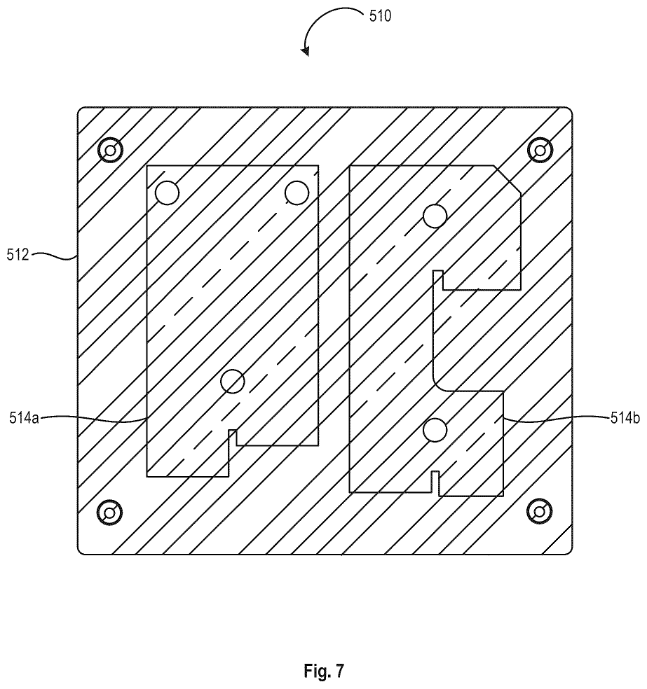

FIG. 7 is a cross-section view of the heat sink assembly 510 of FIG. 6 along the line A-A in FIG. 6. As shown in the cross-section view of FIG. 7, an embedded part of the first segment 514a of the metal portion 514 and an embedded part of the second segment 514b of the metal portion 514 are embedded in the plastic portion 512. The first segment 514a and the second segment 514b are separate from each other and their respective embedded parts are electrically isolated from one another by the plastic portion 512. The first segment 514a and the second segment 514b being electrically isolated from one another allows for the first segment 514a and the second segment 514b to be connected to different conductors within the MSA without forming connections between the different conductors and causing electrical shorts. In an example, the first segment 514a is connected to a positive conductor and the second segment 514b is connected to a negative conductor within the MSA. In an example, the first segment 514a is connected to two positive conductors and the second segment 514b is connected to two negative conductors within the MSA.

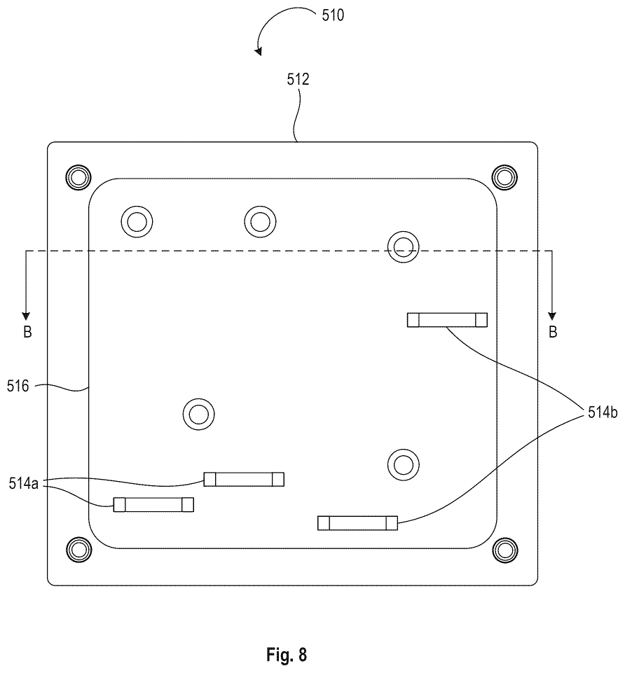

FIG. 8 is a front view of the heat sink assembly 510 of FIG. 5.

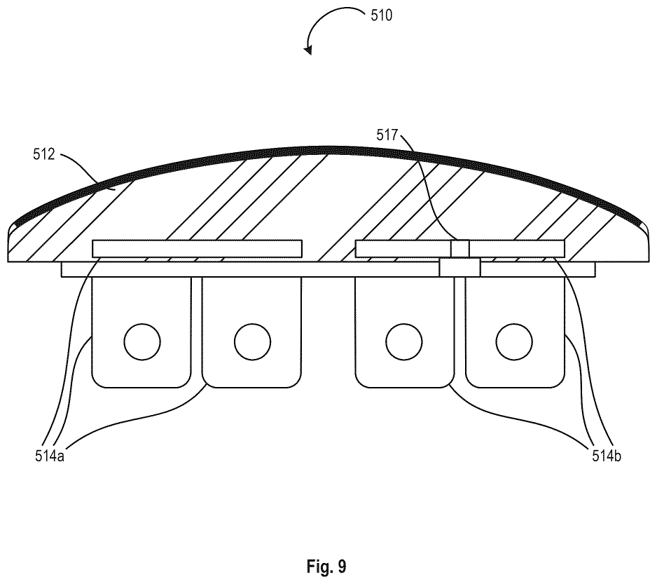

FIG. 9 is a cross-section view of the heat sink assembly 510 of FIG. 8 along the line B-B in FIG. 8. As shown in FIG. 9, the first segment 514a and the second segment 514b of the metal portion 514 extend from within the plastic portion 512 through the back plate 516. In some implementations, an injection port 517 extends through the metal portion 514 and the back plate 516 to allow for plastic material to be injected into a mold to form the plastic portion 512. The metal portion 514 is embedded within the plastic portion 512 by inserting the metal portion 514 into the mold prior to injection. The heat sink assembly 510 may include any number of injection ports. The injection ports may be positioned to facilitate creation of the plastic portion 512 via injection molding.

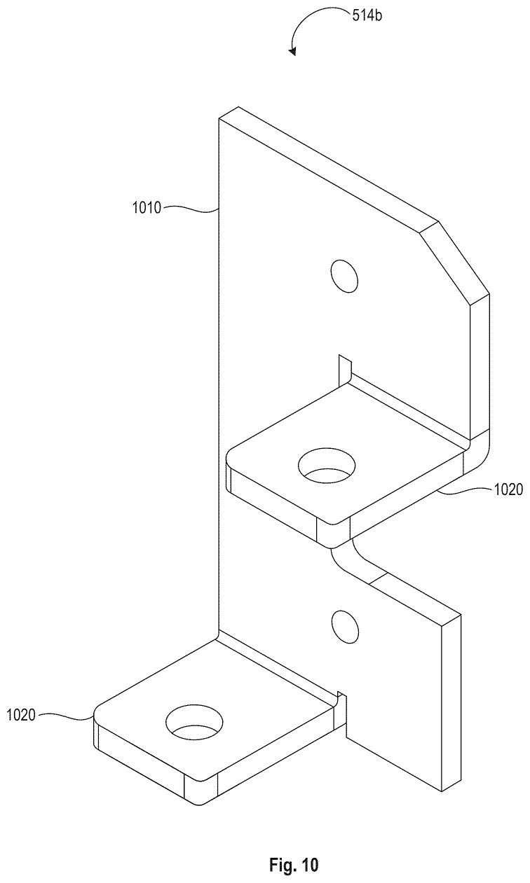

FIG. 10 is a perspective view of the second segment 514b of the metal portion 514 of the heat sink assembly 510 of FIG. 5. The second segment 514b includes an embedded part 1010 and one or more protruding parts 1020. The embedded part 1010 is configured to be embedded within the plastic portion 512. The embedded part 1010 may be embedded within the plastic portion 512 by positioning the second segment 514b within a mold such that the embedded part 1010 is within the mold and the one or more protruding parts 1020 are outside of the mold such that when the plastic portion 512 is formed, the embedded part 1010 is within the plastic portion 512 and the one or more protruding parts 1020 protrude out of the plastic portion 512. The one or more protruding parts 1020 are configured to protrude from the plastic portion 512 (e.g., through the back plate 516) to couple to conductors within an MSA housing. The second segment 514b may be formed from a single sheet of metal. The second segment 514b may be formed by cutting a flat sheet of metal and bending tabs in the flat sheet of metal to form the one or more protruding parts 1020. In some implementations, the one or more protruding parts 1020 are tabs including holes to facilitate attachment to conductors within the MSA.

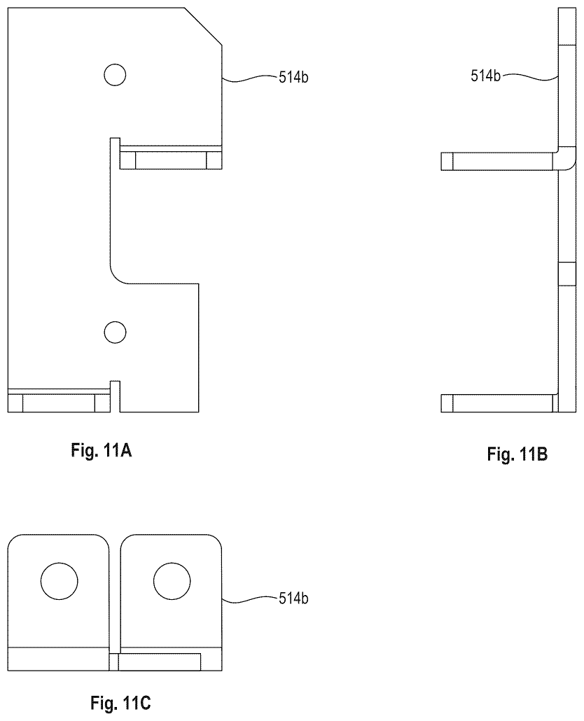

FIG. 11A is a front view of the second segment 514b of FIG. 10. FIG. 11B is a side view of the second segment 514b of FIG. 10. FIG. 11C is a bottom view of the second segment 514b of FIG. 10.

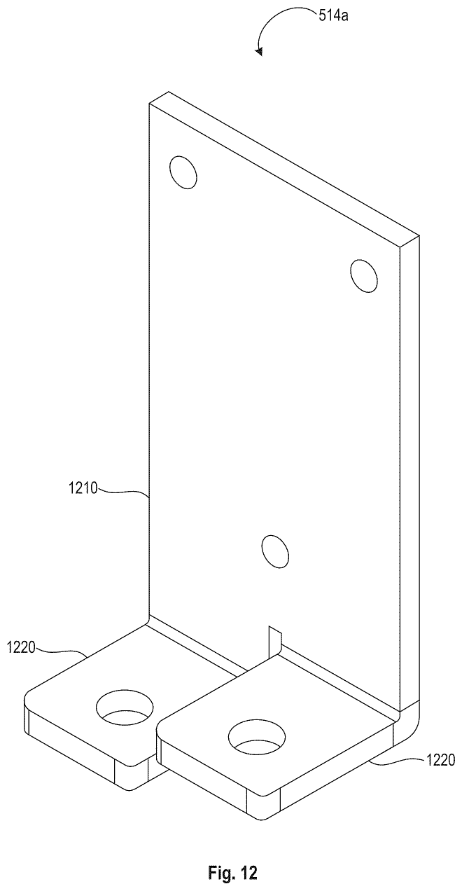

FIG. 12 is a perspective view of the first segment 514a of the metal portion 514 of the heat sink assembly 510 of FIG. 5. The first segment 514a includes an embedded part 1210 and one or more protruding parts 1220. The embedded part 1210 is configured to be embedded within the plastic portion 512. The embedded part 1210 may be embedded within the plastic portion 512 by positioning the second segment 514b within a mold such that the embedded part 1210 is within the mold and the one or more protruding parts 1220 are outside of the mold such that when the plastic portion 512 is formed, the embedded part 1210 is within the plastic portion 512 and the one or more protruding parts 1220 protrude out of the plastic portion 512. The one or more protruding parts 1220 are configured to protrude from the plastic portion 512 (e.g., through the back plate 516) to couple to conductors within an MSA housing. The first segment 514a may be formed from a single sheet of metal. The first segment 514a may be formed by cutting a flat sheet of metal and bending tabs in the flat sheet of metal to form the one or more protruding parts 1220. In some implementations, the one or more protruding parts 1220 are tabs including holes to facilitate attachment to conductors within the MSA.

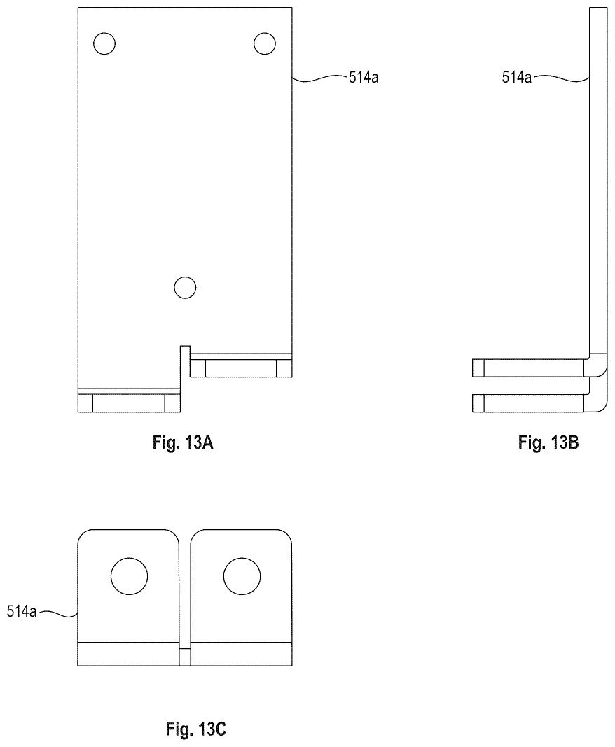

FIG. 13A is a front view of the first segment 514a of FIG. 12. FIG. 13B is a side view of the first segment 514a of FIG. 12. FIG. 13C is a bottom view of the first segment 514a of FIG. 12.

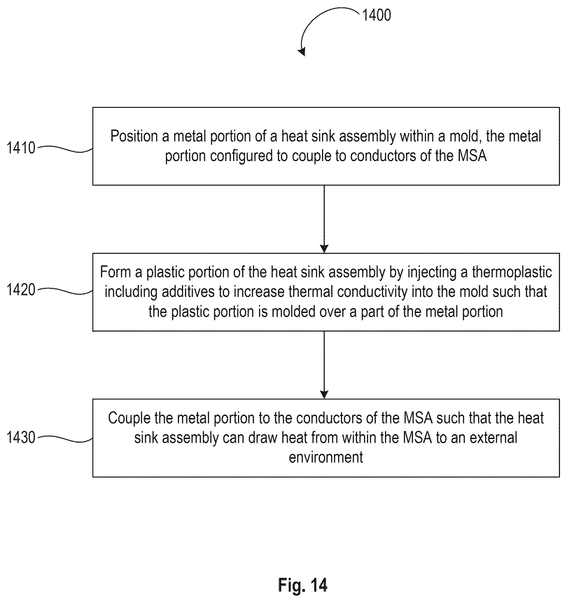

FIG. 14 is a flow chart illustrating operations of a method 1400 for manufacturing a heat sink assembly for an MSA. The method 1400 may include more, fewer, or different operations than shown. The operations may be performed in the order shown, in a different order, or concurrently.

At operation 1410, a metal portion of a heat sink assembly is positioned within a mold. The metal portion is configured to couple (e.g., thermally, electrically) to conductors of the MSA. The metal portion can include multiple different segments that are not connected to each other, allowing the different segments to be coupled to different conductors of the MSA. As discussed herein, the metal portion can be placed within the mold such that an embedded portion of the metal portion is within the mold and a protruding portion of the metal portion is outside of the mold.

At operation 1420, a plastic portion of the heat sink assembly is formed by injecting a thermoplastic including additives to increase thermal conductivity into the mold such that the plastic portion is molded over a part of the metal portion. The plastic portion can be molded over the embedded part of the metal portion. In some implementations, the metal portion includes one or more injection ports for injecting the thermoplastic into the mold through the injection ports. In some implementations, a back plate is added to the heat sink assembly such that the protruding part of the metal portion extends through the back plate.

At operation 1430, the metal portion is coupled to the conductors of the MSA such that the heat sink assembly can draw heat from within the MSA to an external environment. The protruding part of the metal portion can be coupled to the conductors of the MSA such that hat passes from the conductors to the protruding part of the metal portion to the embedded part of the metal portion to the plastic portion to the external environment. The external environment can include ambient air. The plastic portion can include blades to increase a surface area of the plastic portion and facilitate a transfer of heat from the plastic portion to the ambient air.

In some implementations, the mold is configured such that the plastic portion includes blades that are curved to be flush with a cylindrical housing of the MSA. The plastic portion can include any number of blades. The spacing between the blades can represent a balance between strength of the blades, heat transfer, and manufacturing constraints.

The various illustrative logical blocks, circuits, modules, routines, and algorithm steps described in connection with the embodiments disclosed herein can be implemented as electronic hardware, or combinations of electronic hardware and computer software. To clearly illustrate this interchangeability, various illustrative components, blocks, modules, and steps have been described above generally in terms of their functionality. Whether such functionality is implemented as hardware, or as software that runs on hardware, depends upon the particular application and design constraints imposed on the overall system. The described functionality can be implemented in varying ways for each particular application, but such implementation decisions should not be interpreted as causing a departure from the scope of the disclosure.

Moreover, the various illustrative logical blocks and modules described in connection with the embodiments disclosed herein can be implemented or performed by a machine, such as a general purpose processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A control processor can synthesize a model for an FPGA. For example, the control processor can synthesize a model for logical programmable gates to implement a tensor array and/or a pixel array. The control channel can synthesize a model to connect the tensor array and/or pixel array on an FPGA, a reconfigurable chip and/or die, and/or the like. A general purpose processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances, where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A heat sink assembly, comprising:
a metal portion that is electrically conductive and thermally conductive, the metal portion configured to couple to conductors of a meter socket adapter (MSA) to draw heat from the conductors of the MSA; and
a plastic portion that is electrically insulative and thermally conductive, the plastic portion coupled to the metal portion to transfer heat from the metal portion to an exterior of the MSA, wherein the plastic portion is molded over a part of the metal portion.

2. The heat sink assembly of claim 1, wherein the metal portion includes a first metal segment and a second metal segment, the first metal segment coupled to a first conductor of the conductors of the MSA and the second metal segment coupled to a second conductor of the conductors of the MSA.

3. The heat sink assembly of claim 1, wherein the plastic portion includes blades to increase a surface area of the plastic portion.

4. The heat sink assembly of claim 1, wherein the metal portion includes an embedded part that extends laterally within the plastic portion.

5. The heat sink assembly of claim 4, wherein the embedded part extends laterally over at least 50% of an area of the plastic portion.

6. The heat sink assembly of claim 1, wherein an exterior surface of the plastic portion is flush with a housing of the MSA.

7. The heat sink assembly of claim 1, wherein the plastic portion has anisotropic thermal conductivity, and wherein the plastic portion has a higher thermal conductivity in a first direction towards an exterior surface of the plastic portion than in a second direction parallel to the exterior surface of the plastic portion.

8. The heat sink assembly of claim 1, wherein the plastic portion is not grounded.

9. The heat sink assembly of claim 1, wherein the plastic portion is an injection-molded thermoplastic including additives that increase the thermal conductivity of the thermoplastic.

10. A meter socket adapter (MSA), comprising:
a first conductor configured to electrically couple to a meter socket;
a second conductor configured to electrically couple to an electrical meter;
a housing; and
a heat sink assembly, comprising:
a metal portion that is electrically conductive and thermally conductive, the metal portion configured to couple to the first conductor and the second conductor to draw heat from the first conductor and the second conductor; and
a plastic portion that is electrically insulative and thermally conductive, the plastic portion coupled to the metal portion to transfer heat from the metal portion to an exterior of the housing, wherein the plastic portion is molded over a part of the metal portion.

11. The MSA of claim 10, wherein the metal portion includes a first metal segment and a second metal segment, the first metal segment coupled to the first conductor and the second metal segment coupled to the second conductor.

12. The MSA of claim 10, wherein the plastic portion includes blades to increase a surface area of the plastic portion.

13. The MSA of claim 10, wherein the metal portion includes an embedded part that extends laterally within the plastic portion.

14. The MSA of claim 13, wherein the embedded part extends laterally over at least 50% of an area of the plastic portion.

15. The MSA of claim 10, wherein an exterior surface of the plastic portion is flush with the housing.

16. The MSA of claim 10, wherein the plastic portion has anisotropic thermal conductivity, and wherein the plastic portion has a higher thermal conductivity in a first direction towards an exterior surface of the plastic portion than in a second direction parallel to the exterior surface of the plastic portion.

17. The MSA of claim 10, wherein the plastic portion is not grounded.

18. The MSA of claim 10, wherein the plastic portion is an injection-molded thermoplastic including additives that increase the thermal conductivity of the thermoplastic.

19. A method for manufacturing a heat sink assembly for a meter socket adapter (MSA), the method comprising:
positioning a metal portion of the heat sink assembly within a mold, the metal portion configured to couple to conductors of the MSA; and
forming a plastic portion of the heat sink assembly by injecting a thermoplastic including additives to increase thermal conductivity into the mold such that the plastic portion is molded over a part of the metal portion.

20. The method of claim 19, wherein the mold is configured such that the plastic portion includes blades that are curved to be flush with a cylindrical housing of the MSA.
